(19) United States
(12) Patent Application Publication
(10) Pub. No.: US 2019/0158040 A1
(43) Pub. Date: May 23, 2019

(54) Enhanced Reverse Isolation and Gain Using Feedback

(71) Applicant: Qualcomm Incorporated, San Diego, CA (US)

(72) Inventors: Alaaeldien Mohamed Abdelrazek Medra, San Diego, CA (US); David Zixiang Yang, San Diego, CA (US); Francesco Gatta, San Diego, CA (US)

(21) Appl. No.: 16/049,473

(22) Filed: Jul. 30, 2018

Related U.S. Application Data
(60) Provisional application No. 62/588,249, filed on Nov. 17, 2017.

(51) Int. Cl. H03F 1/34; H03F 3/195; H03F 1/56

(52) U.S. Cl. CPC H03F 1/342; H03F 3/195; H03F 1/565; H03F 2200/129; H03F 2200/156; H03F 2200/27; H03F 2200/429; H03F 2200/165; H03F 2200/451; H03F 2200/249; H03F 2200/267; H03F 2200/541; H03F 2200/387; H03F 2200/294

(57) ABSTRACT

An apparatus is disclosed for enhanced reverse isolation and gain using feedback. The apparatus includes an input node, an amplification node, a feedback node, an output circuit, at least one amplifier circuit, and a feedback circuit. The output circuit is connected between the amplification node and the feedback node. The at least one amplifier circuit is connected between the input node and the amplification node. The at least one amplifier circuit includes an input transistor and a cascode stage. The input transistor has a gate node and a drain node, and the gate node is connected to the input node. The cascode stage is connected between the drain node and the amplification node. The feedback circuit includes at least one feedback capacitor that is connected between the feedback node and the input node.

### CROSS-REFERENCE TO RELATED APPLICATION(S)

This application claims the benefit of U.S. Provisional Application No. 62/588,249 filed 17 Nov. 2017, the disclosure of which is hereby incorporated by reference in its entirety herein.

### TECHNICAL FIELD

This disclosure relates generally to amplifiers and, more specifically, to using feedback to enhance reverse isolation and gain for low-noise amplifiers.

### BACKGROUND

Electronic devices use radio-frequency (RF) signals to communicate information. These radio-frequency signals enable users to talk with friends, download information, share pictures, remotely control household devices, receive global positioning information, employ radar for detection and tracking, or listen to radio stations. As a distance over which these radio-frequency signals travel increases, it becomes increasingly challenging to distinguish the radio-frequency signals from background noise. To address this issue, electronic devices use low-noise amplifiers (LNAs), which amplify a radio-frequency signal without introducing significant additional noise. Performance of a low-noise amplifier depends on several factors, including impedance matching.

Impedance mismatch, for example, can cause a portion of an output signal of a low-noise amplifier to be reflected back to an output port of the low-noise amplifier such that the reflected signal enters the low-noise amplifier. To some degree, the reflected signal may propagate through the low-noise amplifier to an input of the low-noise amplifier. Without sufficient reverse isolation, the reflected signal, which is flowing in a reverse direction from the output to the input, can interfere with a signal that is flowing in a forward direction from the input to the output. Consequently, the low-noise amplifier can become unstable and be unable to provide satisfactory amplification. It is challenging, however, to design a low-noise amplifier that can realize sufficient reverse isolation to provide satisfactory amplification.

### SUMMARY

An apparatus is disclosed that implements enhanced reverse isolation and gain using feedback. In particular, a low-noise amplifier includes an amplifier circuit and a feedback circuit. The amplifier circuit includes an input transistor, which has a gate node and a drain node. The feedback circuit injects a feedback current into the gate node to compensate for a gate-to-drain current that flows between the gate node and the drain node during operation. By providing at least a portion of the gate-to-drain current, the feedback current improves reverse isolation performance of the low-noise amplifier. With enhanced reverse isolation, the amplifier circuit can comprise a single cascode stage, provide sufficient amplification using a smaller supply voltage, and mitigate the effects of impedance mismatching.

In an example aspect, an apparatus is disclosed. The apparatus includes an input node, an amplification node, a feedback node, an output circuit, at least one amplifier circuit, and a feedback circuit. The output circuit is connected between the amplification node and the feedback node. The at least one amplifier circuit is connected between the input node and the amplification node. The at least one amplifier circuit includes an input transistor and a cascode stage. The input transistor has a gate node and a drain node, and the gate node is connected to the input node. The cascode stage is connected between the drain node and the amplification node. The feedback circuit includes at least one feedback capacitor that is connected between the feedback node and the input node.

In an example aspect, an apparatus is disclosed. The apparatus includes an input node, an amplification node, a feedback node, and at least one amplifier circuit. The at least one amplifier circuit is connected between the input node and the amplification node. The at least one amplifier circuit includes an input transistor and a cascode stage. The input transistor has a gate node, a drain node, and a gate-to-drain capacitance. The gate node is connected to the input node. The cascode stage is connected between the drain node and the amplification node. The apparatus also includes mutual coupling means for producing, at the feedback node, a feedback voltage that is substantially opposite in phase to an amplified voltage at the amplification node. The mutual coupling means is connected between the amplification node and the feedback node. The apparatus additionally includes feedback means for providing, based on the feedback voltage, a feedback current at the input node. The feedback current provides at least a portion of a gate-to-drain current that flows between the gate node and the drain node through the gate-to-drain capacitance during operation.

In an example aspect, a method for enhanced reverse isolation and gain using feedback is disclosed. The method includes accepting a forward signal and a reverse signal. The method also includes propagating at least a portion of the forward signal and at least a portion of the reverse signal through a gate-to-drain capacitance that exists between a gate node and a drain node of a transistor. The method additionally includes providing a feedback current at the gate node. The feedback current comprises a first current that is substantially in phase with the forward signal and a second current that is substantially opposite in phase with the reverse signal. Via the first current, the method includes amplifying the forward signal at the gate node. Via the second current, the method includes attenuating the reverse signal at the gate node.

In an example aspect, an apparatus is disclosed. The apparatus includes multiple band-pass filters having different frequency bands, a switch module connected to the multiple band-pass filters, and a low-noise amplifier connected to the switch module. The low-noise amplifier includes at least one amplifier circuit connected to the switch module, an output circuit connected to the at least one amplifier circuit at an amplification node. The output circuit is configured to produce, at a feedback node, a feedback voltage that is substantially opposite in phase to an amplified voltage at the amplification node. The low-noise amplifier also includes a feedback circuit connected between the feedback node and the at least one amplifier circuit. The feedback circuit is configured to provide a feedback current to the at least one amplifier circuit based on the feedback voltage.

### BRIEF DESCRIPTION OF DRAWINGS

FIG. 1 illustrates an example environment for enhanced reverse isolation and gain using feedback.

FIG. 2 illustrates a portion of an example wireless transceiver for enhanced reverse isolation and gain using feedback.

FIG. 3 illustrates an example implementation of a portion of a wireless transceiver for enhanced reverse isolation and gain using feedback.

FIG. 4 illustrates an example low-noise amplifier that implements enhanced reverse isolation and gain using feedback.

FIG. 5 illustrates a graph depicting examples of a gate voltage and a drain voltage for enhanced reverse isolation and gain using feedback.

FIG. 6 illustrates another example low-noise amplifier that implements enhanced reverse isolation and gain using feedback.

FIG. 7 is a flow diagram illustrating an example process for enhanced reverse isolation and gain using feedback.

### DETAILED DESCRIPTION

Electronic devices use low-noise amplifiers (LNAs) to support radio-frequency communication. It becomes challenging, however, to design a low-noise amplifier that can achieve a target performance level in the presence of impedance mismatching and a limited supply voltage. The low-noise amplifier, for example, may be connected to another component (e.g., another amplifier or a mixer) that has a mismatched impedance or an isolation deficiency. This impedance mismatch can cause a signal that is generated by the low-noise amplifier to be reflected at an output of the low-noise amplifier and propagate through the low-noise amplifier to an input of the low-noise amplifier. Without sufficient reverse isolation, the reflected signal, which is flowing in a reverse direction from the output to the input, can interfere with a desired signal that is flowing in a forward direction from the input to the output. Consequently, the low-noise amplifier can become unstable and be unable to provide even satisfactory amplification.

The term “reverse isolation” refers to an ability of the low-noise amplifier to isolate the output from the input. Generally speaking, reverse isolation represents an amount that a signal injected at the output of the low-noise amplifier is attenuated at the input of the low-noise amplifier. In other words, reverse isolation is a response of the low-noise amplifier, as seen from the input, to the signal that is presented at the output. The reverse isolation of a low-noise amplifier is also referred to as a reverse voltage gain or S12, which is a scattering parameter wherein the input and the output respectively correspond to port 1 and port 2. The reverse isolation also characterizes an ability of the low-noise amplifier to mitigate the effects of the impedance mismatching with a downstream component.

If an electronic device utilizes a smaller supply voltage to conserve power and facilitate battery-powered mobile operations, some low-noise amplifier designs may no longer be suitable. Although a multiple cascode configuration, for example, may be able to provide sufficient reverse isolation, the multiple intrinsic voltage drops across the multiple cascode stages consume significant voltage headroom, which represents a voltage difference between a supply voltage and ground. Because an energy-efficient, smaller supply voltage provides a smaller voltage headroom, a low-noise amplifier may not have sufficient voltage headroom for amplification via the multiple cascode configuration.

Instead of using the multiple cascode configuration, a low-noise amplifier having a single cascode configuration can provide amplification using a smaller supply voltage. The single cascode configuration, however, has several disadvantages compared to the multiple cascode configuration. In comparing a double cascode configuration to a single cascode configuration that is substantially similar with the exception that one of the cascodes is removed, the single cascode configuration has less reverse isolation and a smaller gain compared to the double cascode configuration.

In contrast with the above, example approaches are described herein for enhanced reverse isolation and gain using feedback. In particular, a low-noise amplifier includes an amplifier circuit, an output circuit, and a feedback circuit. The amplifier circuit includes an input transistor, which has a gate node and a drain node. Between the gate node and the drain node, a parasitic capacitance exists, which enables a gate-to-drain current to flow between the gate node and the drain node during operation (e.g., flow from the gate node to the drain node or from the drain node to the gate node). The amplifier circuit is coupled to the output circuit at an amplification node and the output circuit is coupled to the feedback circuit at a feedback node. The output circuit causes a feedback voltage at the feedback node to be substantially opposite in phase to an amplified voltage at the amplification node. Based on the feedback voltage, the feedback circuit injects a feedback current into the gate node of the input transistor to compensate for the gate-to-drain current. By providing at least a portion of the gate-to-drain current, the feedback current improves both reverse isolation performance and a gain of the low-noise amplifier. In considering reverse isolation, the output circuit and the feedback circuit cause a reverse signal that propagates through the amplifier circuit from the amplification node to the gate node to be attenuated via at least a portion of the feedback current. This attenuation significantly reduces a presence of the reverse signal at an input node of the low-noise amplifier. In terms of gain, at least another portion of the feedback current amplifies an input signal at the gate node, which compensates for a portion of the input signal that leaks through the gate-to-drain capacitance. With these enhancements, the amplifier circuit can comprise a single cascode stage, provide sufficient amplification using a smaller supply voltage, and mitigate the effects of impedance mismatching.

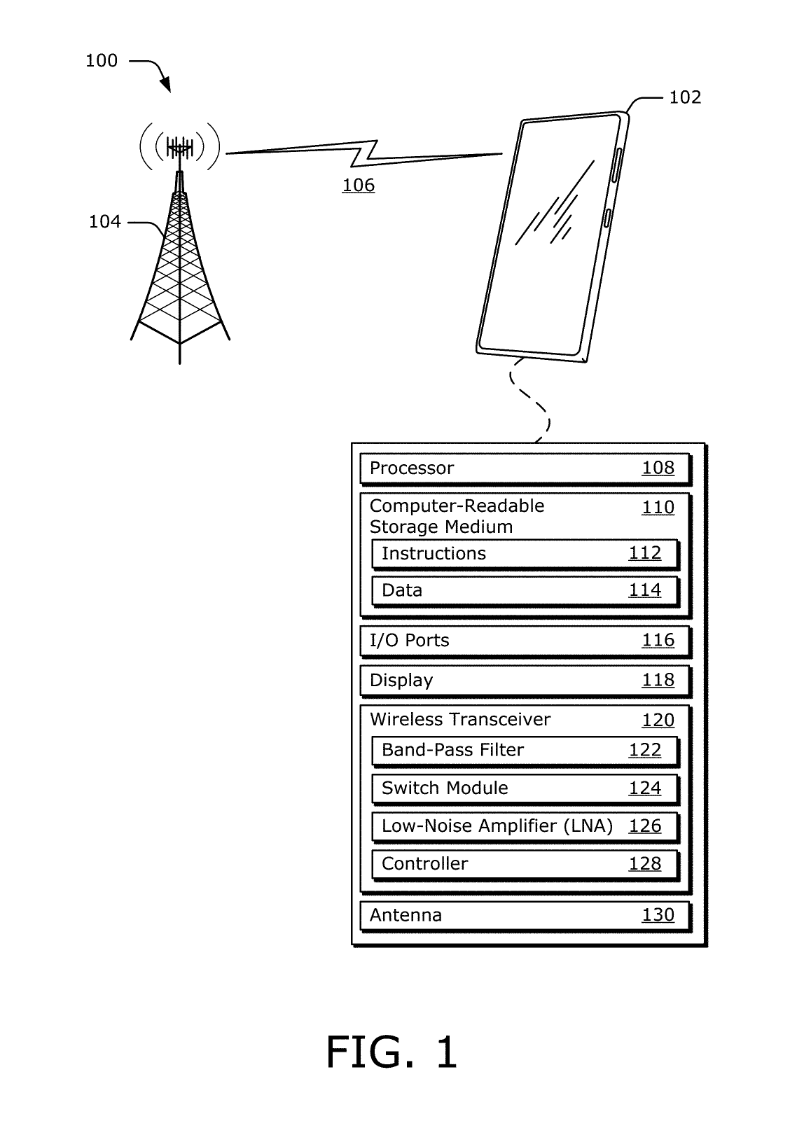

FIG. 1 illustrates an example environment 100, which includes a computing device 102 that communicates with a base station 104 through a wireless communication link 106 (wireless link 106). In this example, the computing device 102 is implemented as a smart phone. However, the computing device 102 may be implemented as any suitable computing or electronic device, such as a modem, cellular base station, broadband router, access point, cellular phone, gaming device, navigation device, media device, laptop computer, desktop computer, tablet computer, server, network-attached storage (NAS) device, smart appliance, vehicle-based communication system, Internet-of-Things (IoT) device, and so forth.

The base station 104 communicates with the computing device 102 via the wireless link 106, which may be implemented as any suitable type of wireless link. Although depicted as a tower of a cellular network, the base station 104 may represent or be implemented as another device, such as a satellite, cable television head-end, terrestrial television broadcast tower, access point, peer-to-peer device, mesh network node, fiber optic line, and so forth. Therefore, the computing device 102 may communicate with the base station 104 or another device via a wired connection, a wireless connection, or a combination thereof.

The wireless link 106 can include a downlink of data or control information communicated from the base station 104 to the computing device 102 and an uplink of other data or control information communicated from the computing device 102 to the base station 104. The wireless link 106 may be implemented using any suitable communication protocol or standard, such as 3rd Generation Partnership Project Long-Term Evolution (3GPP LTE), 5th Generation (5G), IEEE 802.11, IEEE 802.16, Bluetooth™, and so forth.

As illustrated, the computing device 102 includes at least one processor 108 and at least one computer-readable storage medium 110 (CRM 110). The processor 108 may include any type of processor, such as an application processor or multi-core processor, that is configured to execute processor-executable code stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the computing device 102, and thus does not include transitory propagating signals or carrier waves.

The computing device 102 may also include input/output ports 116 (I/O ports 116) and a display 118. The I/O ports 116 enable data exchanges or interaction with other devices, networks, or users. The I/O ports 116 may include serial ports (e.g., universal serial bus (USB) ports), parallel ports, audio ports, infrared (IR) ports, and so forth. The display 118 presents graphics of the computing device 102, such as a user interface associated with an operating system, program, or application. Alternately or additionally, the display 118 may be implemented as a display port or virtual interface, through which graphical content of the computing device 102 is presented.

A wireless transceiver 120 of the computing device 102 provides connectivity to respective networks and other electronic devices connected therewith. Alternately or additionally, the computing device 102 may include a wired transceiver, such as an Ethernet or fiber optic interface for communicating over a local network, intranet, or the Internet. The wireless transceiver 120 may facilitate communication over any suitable type of wireless network, such as a wireless LAN (WLAN), peer-to-peer (P2P) network, mesh network, cellular network, wireless wide-area-network (WWAN), and/or wireless personal-area-network (WPAN). In the context of the example environment 100, the wireless transceiver 120 enables the computing device 102 to communicate with the base station 104 and networks connected therewith.

The wireless transceiver 120 includes circuitry and logic, such as filters, switches, amplifiers, mixers, and so forth, for conditioning signals that are transmitted or received via at least one antenna 130. The wireless transceiver 120 may also include logic to perform in-phase/quadrature (I/Q) operations, such as synthesis, encoding, modulation, decoding, demodulation, and so forth. In some cases, components of the wireless transceiver 120 are implemented as separate receiver and transmitter entities. Additionally or alternatively, the wireless transceiver 120 can be realized using multiple or different sections to implement respective receiving and transmitting operations (e.g., separate receive and transmit chains). The wireless transceiver 120 also includes a baseband modem (not shown) to process data and/or signals associated with communicating data of the computing device 102 over the antenna 130. The baseband modem may be implemented as a system-on-chip (SoC) that provides a digital communication interface for data, voice, messaging, and other applications of the computing device 102. The baseband modem may also include baseband circuitry to perform high-rate sampling processes that can include analog-to-digital conversion, digital-to-analog conversion, gain correction, skew correction, frequency translation, and so forth.

As shown, the wireless transceiver includes at least one band-pass filter 122, at least one switch module 124, at least one low-noise amplifier (LNA) 126, and at least one controller 128. The band-pass filter 122 can be implemented with acoustic resonators, such as surface acoustic wave (SAW) resonators or bulk-acoustic wave (BAW) resonators. In some cases, the band-pass filter 122 can comprise multiple band-pass filters 122, which pass different frequency bands (e.g., have different passbands), such as frequency bands 1, 3, 66, and so forth. The band-pass filter 122 filters a signal that is received via the antenna 130 to produce a filtered signal.

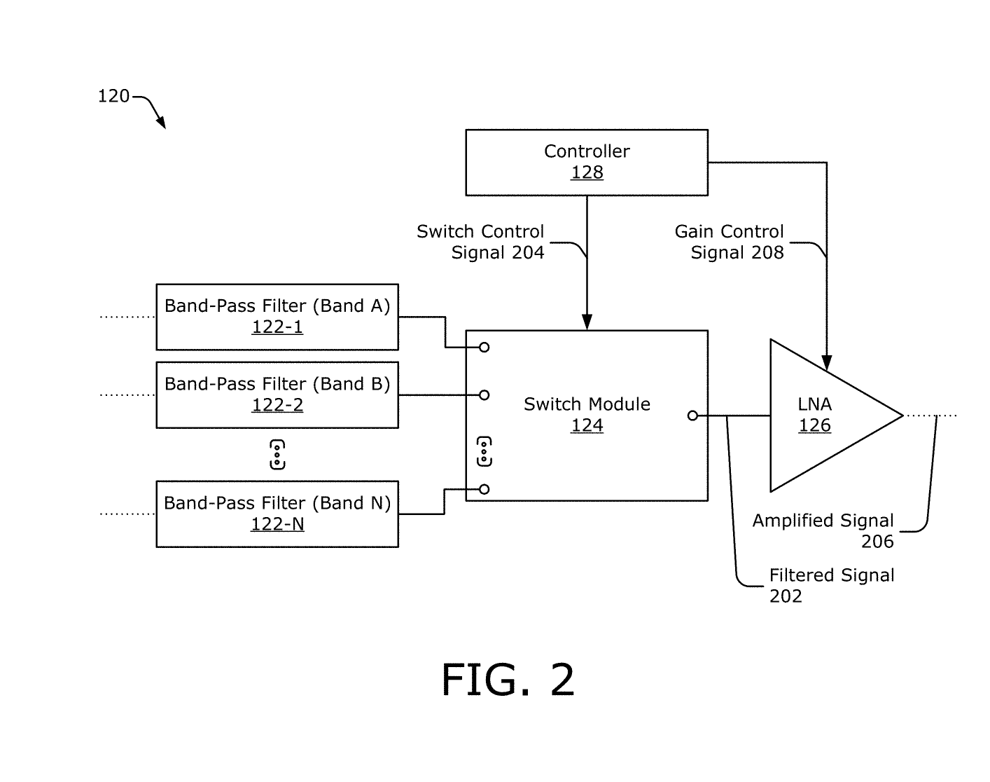

The switch module 124 includes at least one switch that connects or disconnects the band-pass filter 122 to or from the low-noise amplifier 126. As used herein, the term “connect” or “connected” refers to an electrical connection, including a direct connection (e.g., connecting discrete circuit elements via a same node) or an indirect connection (e.g., connecting discrete circuit elements via one or more other devices or other discrete circuit elements). Assuming there are multiple band-pass filters 122, the switch module 124 can include multiple switches that respectively connect, one at a time, each of the multiple band-pass filters 122 to the low-noise amplifier 126. In general, the switch module 124 enables the filtered signal that is produced by the connected band-pass filter 122 to be provided to the low-noise amplifier 126. The low-noise amplifier 126, which is described with reference to FIGS. 2-4 and 6, can at least partially implement enhanced reverse isolation and gain using feedback. The low-noise amplifier 126 and the controller 128 are further described with respect to FIG. 2.

FIG. 2 illustrates a portion of the wireless transceiver 120 for enhanced reverse isolation and gain using feedback. In the depicted configuration, the wireless transceiver 120 is shown to include multiple band-pass filters 122-1, 122-2 . . . 122-N, the switch module 124, the low-noise amplifier 126, and the controller 128. The multiple band-pass filters 122-1, 122-2 . . . 122-N, the switch module 124, and the low-noise amplifier 126 implement a portion of a receiver chain of the wireless transceiver 120. Although not shown, the band-pass filters 122-1, 122-2 . . . 122-N can be connected to other components of the wireless transceiver 120, such as the antenna 130. The multiple band-pass filters 122-1, 122-2 . . . 122-N are connected to respective inputs of the switch module 124. An output of the switch module 124 is connected to the low-noise amplifier 126. The low-noise amplifier 126 can be connected to other components of the wireless transceiver 120, such as other amplifiers or mixers.

The multiple band-pass filters 122-1, 122-2 . . . 122-N are designed to pass different frequency bands. For instance, the multiple band-pass filters 122-1, 122-2 . . . 122-N are configured to pass respective frequency bands A, B, and N. The switch module 124 selects one of the multiple band-pass filters 122-1, 122-2 . . . 122-N for providing a filtered signal 202, which comprises a single-ended signal, to the low-noise amplifier 126. The switch module 124 may perform the selection based on a switch control signal 204 that is provided via the controller 128. The switch control signal 204 can specify configurations of multiple switches (not shown) in the switch module 124.

The low-noise amplifier 126 amplifies the filtered signal 202 that is obtained from the connected (e.g., selected) band-pass filter 122 to produce an amplified signal 206. In some cases, the low-noise amplifier 126 can obtain from the controller 128 a gain control signal 208, which specifies a target amount of amplification of the filtered signal 202. The wireless transceiver 120 can provide the amplified signal 206 to a baseband modem (not shown) for further processing.

The controller 128 includes control circuitry to generate the switch control signal 204 and the gain control signal 208. The controller 128 can respectively route the switch control signal 204 and the gain control signal 208 to the switch module 124 and the low-noise amplifier 126 via a communication interface, such as a serial bus. In some implementations, the mobile industry processor interface (MIPI) radio-frequency front-end (RFFE) interface standard may be used for communicating these control signals. One or more registers may also be used to store and provide access to information that is carried by the switch control signal 204 or the gain control signal 208. The controller 128, for example, can write to the register upon startup or during operation of the wireless transceiver 120.

The controller 128 may also be responsible for setting or controlling an operational mode of the wireless transceiver 120. The operational mode can be associated with a communication frequency band the wireless transceiver 120 may receive or a gain mode of the low-noise amplifier 126. In this way, the controller 128 can determine the appropriate information to convey in the switch control signal 204 or the gain control signal 208 based on the current operational mode. The controller 128 may also reference information that is stored in the computer-readable storage medium 110 for generating the switch control signal 204 or the gain control signal 208.

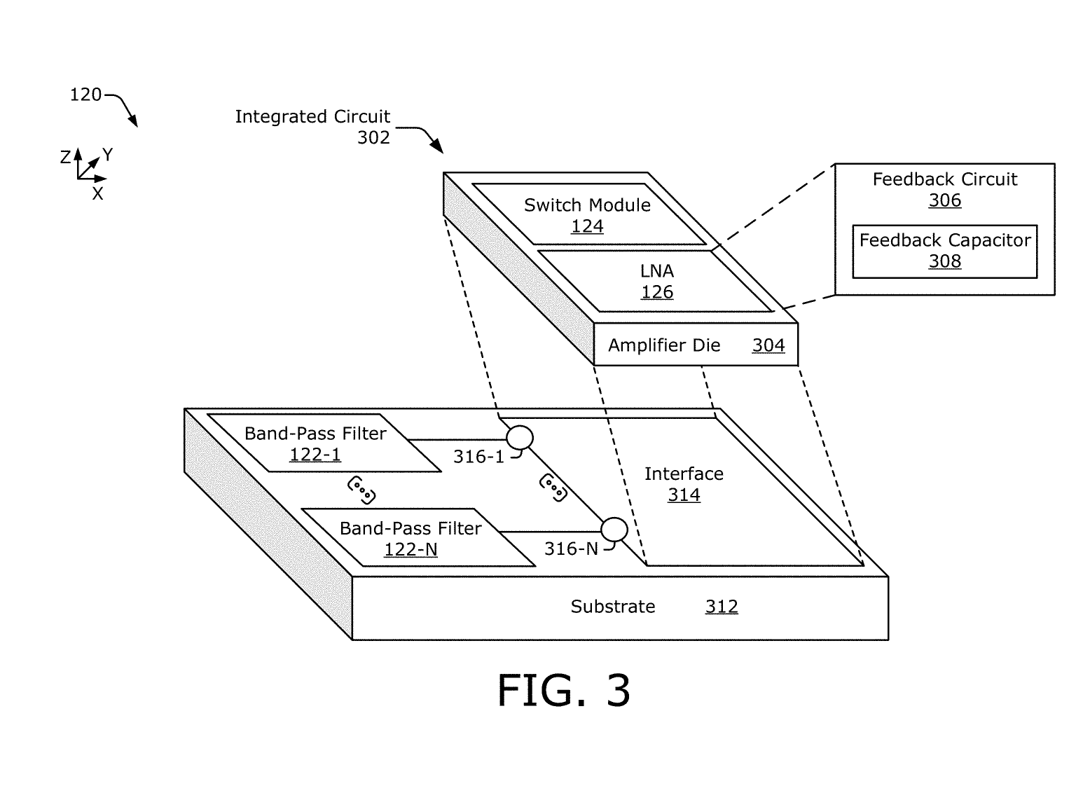

To specify the switch configuration of the switch module 124, the controller 128 can determine a frequency band of a wireless communication signal that the wireless transceiver 120 may receive. For example, if the wireless communication signal is within the frequency band A, the controller 128 can generate the switch control signal 204 to cause the switch module 124 to connect the band-pass filter 122-1 to the low-noise amplifier 126. The controller 128 can also determine a target amplification of the wireless communication signal or a target power mode of the computing device 102 for performing the wireless communication. This determination may be based on information provided by the processor 108, such as a measured distance between the base station 104 and the computing device 102, predetermined communication performance, available power of the computing device 102 (e.g., remaining battery power), and so forth. Accordingly, the controller 128 can use this information to specify a gain of the low-noise amplifier 126. In some implementations, the switch module 124 and the low-noise amplifier 126 are implemented on a same integrated circuit, as shown in FIG. 3.

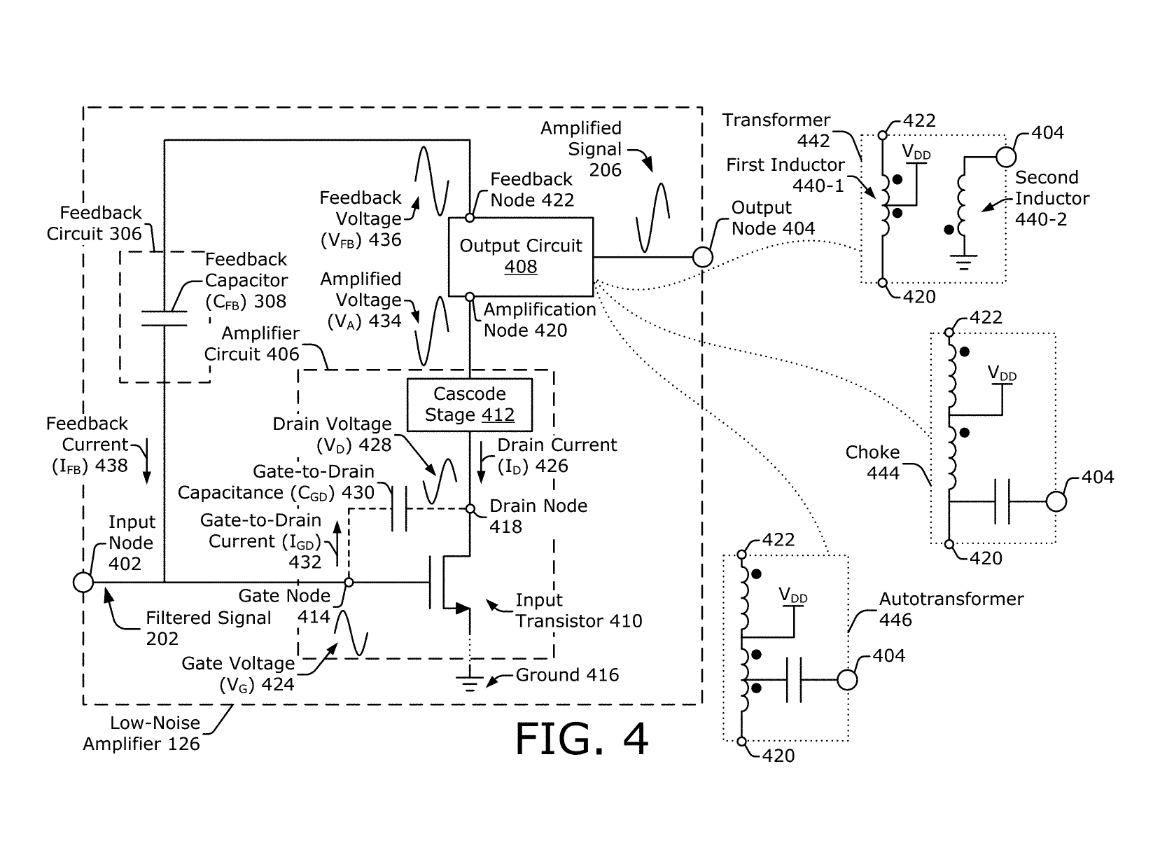

FIG. 3 illustrates an example implementation of the wireless transceiver 120 for enhanced reverse isolation and gain using feedback. The wireless transceiver 120 includes an integrated circuit 302 implemented on an amplifier die 304. The integrated circuit 302 includes the switch module 124 and the low-noise amplifier 126. The low-noise amplifier 126 includes a feedback circuit 306, which includes at least one feedback capacitor 308, as also shown in FIG. 4. Although not shown, the feedback circuit 306 can alternatively be implemented using at least one feedback inductor or a combination of one or more feedback capacitors 308 and one or more feedback inductors.

The integrated circuit 302 can be mounted to a substrate 312, which includes an interface 314, multiple input terminals 316-1 . . . 316-N, and the multiple band-pass filters 122-1 . . . 122-N. As shown in FIG. 3, the multiple band-pass filters 122-1 . . . 122-N can be separate from the integrated circuit 302. The interface 314, which is disposed on a surface of the substrate 312, is configured to accept and connect to the amplifier die 304. The multiple input terminals 316-1 . . . 316-N are shown to be respectively connected to the multiple band-pass filters 122-1 . . . 122-N. The interface 314 can also include other terminals for communicating the switch control signal 204 or the gain control signal 208 (of FIG. 2) or providing the amplified signal 206 to other components of the wireless transceiver 120. The feedback circuit 306 and other aspects of the low-noise amplifier 126 are further described with respect to FIGS. 4-6.

FIG. 4 illustrates an example low-noise amplifier 126 for enhanced reverse isolation and gain using feedback. The low-noise amplifier 126 includes an input node 402, an output node 404, at least one amplifier circuit 406, an output circuit 408, and a feedback circuit 306. The amplifier circuit 406 includes an input transistor 410 and a cascode stage 412. In the depicted configuration, the input transistor 410 is shown to be an n-channel metal-oxide-semiconductor field-effect transistor (MOSFET), which is configured as a common-source amplifier. The input transistor 410 has a gate connected to a gate node 414, a source connected to a ground 416, and a drain connected to a drain node 418. The gate node 414 is also connected to the input node 402. Although the gate node 414 and the input node 402 are described separately, the gate node 414 and the input node 402 can represent a single node, which is depicted in FIG. 4. The cascode stage 412 is connected between the drain node 418 and an amplification node 420. The cascode stage 412 can be implemented using, for example, another transistor (e.g., another n-channel MOSFET) that is configured as a common-gate amplifier. Although not depicted, the amplifier circuit 406 can include other components such as a degeneration resistor or a degeneration inductor connected between the source of the input transistor 410 and the ground 416. The output circuit 408 is connected to the output node 404, the amplifier circuit 406 at the amplification node 420, and the feedback circuit 306 at a feedback node 422. Example implementations of the output circuit 408 include a transformer 442, a choke 444, or an autotransformer 446, which are illustrated on the right side of FIG. 4. The transformer 442 includes a first inductor 440-1, which is connected between the amplification node 420 and the feedback node 422, and a second inductor 440-2, which is connected between the output node 404 and an alternating current (AC) ground node. Between the two end terminals of the first inductor 440-1 (e.g., between the amplification node 420 and the feedback node 422), an intermediate tap connects the first inductor to a power supply, which provides a supply voltage VDD. As shown using the dot-convention, a first current that flows through the first inductor 440-1 from the supply voltage to the amplification node 420 induces a second current in the first inductor 440-1 that flows from the first inductor 440-1 to the feedback node 422. The first current also induces a third current in the second inductor 440-2 that flows from the second inductor 440-2 to the ground. The choke 444 and the autotransformer 446 are similarly configured as described above with respect to the transformer 442 and as shown via the dot-convention. In this way, the output circuit 408 magnetically couples the feedback node 422 to the amplification node 420 such that a feedback voltage (V_{FB}) 436 at the feedback node 422 is substantially opposite in phase relative to an amplified voltage (VA) 434 at the amplification node 420. By being substantially opposite in phase, the feedback voltage 436 may be considered to be rotated in phase by approximately 180 degrees with respect to the amplified voltage 434 or to be between approximately 175 and 185 degrees out-of-phase relative to the amplified voltage 434. Depending on the configuration, the output circuit 408 produces a voltage at the output node 404 having a phase that is similar or different to a phase of the amplified voltage 434 at the amplification node 420. The output circuit 408 can also provide impedance matching for the low-noise amplifier 126 by transforming an output impedance of the low-noise amplifier 126 to a predetermined value, such as 50 ohms.

The feedback circuit 306 is connected between the feedback node 422 and the input node 402 (e.g., the gate node 414) and includes the feedback capacitor (C_{FB}) 308. In some implementations, the feedback capacitor 308 is implemented as a variable (e.g., programmable) capacitor whose capacitance is established or set via the gain control signal 208 of FIG. 2.

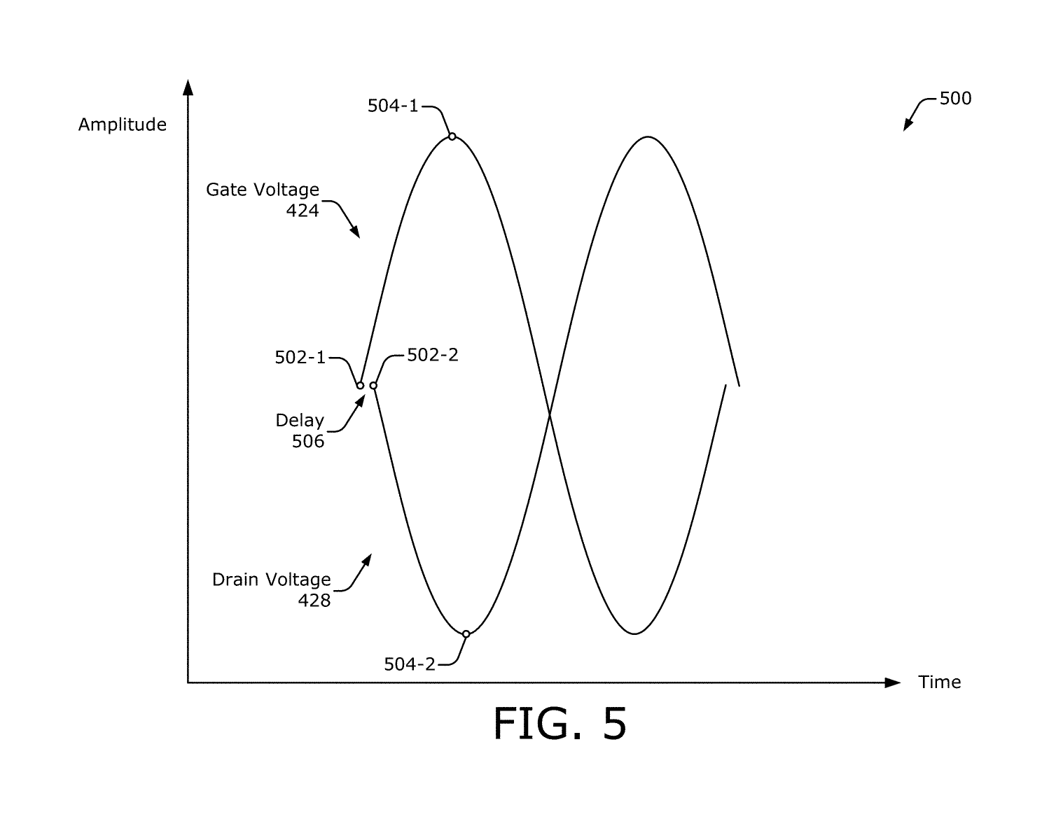

At the input node 402, the low-noise amplifier 126 accepts the filtered signal 202 (e.g., a forward signal), which is provided to the gate node 414. The filtered signal 202 contributes to at least a portion of a gate voltage (V_{G}) 424. Based on the gate voltage 424, the input transistor 410 produces a drain current (I_{D}) 426, which causes a drain voltage (V_{D}) 428 at the drain node 418 to be substantially opposite in phase from the gate voltage 424. The drain voltage 428 may also be approximately equal in magnitude to the gate voltage 424 in some implementations. Generally speaking, the input transistor 410 implements an inverting stage within the amplifier circuit 406. A comparison of the drain voltage 428 and the gate voltage 424 is shown in FIG. 5.

FIG. 5 illustrates a graph 500 depicting an example gate voltage 424 and an example drain voltage 428 for enhanced reverse isolation and gain using feedback. A portion of the gate voltage 424 and a corresponding portion of the drain voltage 428 are represented over time. For illustration purposes, FIG. 5 is not necessarily drawn to scale.

In the graph 500, a first voltage value 502-1 and a second voltage value 504-1 of the gate voltage 424 correspond to a first voltage value 502-2 and a second voltage value 504-2 of the drain voltage 428. The differences in amplitude between these voltage values represents the phase rotation that occurs due to the input transistor 410. In general, the phase rotation is relatively immediate; however, a delay 506 can occur between the gate voltage 424 and the drain voltage 428 due to a layout of the low-noise amplifier 126 and circuit parasitics. This delay 506 is typically insignificant and small relative to a period of the filtered signal 202. Furthermore, although the amplitudes of the gate voltage 424 and the drain voltage 428 are shown to be relatively similar, the amplitudes can be different.

Returning to FIG. 4, a gate-to-drain capacitance (C_{GD}) 430 is present between the gate node 414 and the drain node 418. The gate-to-drain capacitance 430 can include an intrinsic capacitance of the input transistor 410 as well as an extrinsic capacitance resulting from the routing and the input transistor 410 layout. Due to a voltage difference across the gate node 414 and the drain node 418 (e.g., V_{G}−V_{D}), a gate-to-drain current (I_{GD}) 432 exists and flows between the gate node 414 and the drain node 418 through the gate-to-drain capacitance 430 during operation of the input transistor 410. Depending on a voltage phase at the gate node 414 and the drain node 418, the gate-to-drain current 432 can flow from the gate node 414 to the drain node 418 or from the drain node 418 to the gate node 414.

In some situations, at least a portion of the gate-to-drain current 432 may be associated with a portion of the filtered signal 202 that propagates through the gate-to-drain capacitance 430. Without the feedback circuit 306, the portion of the filtered signal 202 may attenuate the drain voltage 428 at the drain node 418 and degrade amplification performance of the low-noise amplifier 126. In other situations, a reverse signal (e.g., a portion of the amplified signal 206 that is reflected at the output node 404 or a spurious signal that is accepted at the output node 404) is accepted by the output circuit 408 from the output node 404. Based on the reverse signal, the output circuit 408 can produce at least a portion of the amplified voltage 434. The reverse signal can propagate through the through the amplifier circuit 406 and the gate-to-drain capacitance 430 based on the amplified voltage 434. In this manner, at least a portion of the gate-to-drain current 432 may be associated with the reverse signal. Without the feedback circuit 306, the reverse signal can appear at the input node 402 and degrade reverse isolation performance of the low-noise amplifier 126 or attenuate the filtered signal 202.

The gate-to-drain current 432 is represented by Equation 1 below, with s representing a complex frequency (s=jω).

I_{GD}=sC_{GD}(V_{G}−V_{D})≈2sC_{GD}V_{G} Equation 1

As shown in Equation 1, the gate-to-drain current 432 is dependent upon the gate-to-drain capacitance 430 and the gate voltage 424.

At the amplification node 420, the cascode stage 412 produces at least a portion of the amplified voltage 434 based on the drain voltage 428, a gain of the cascode stage 412, and an output impedance at the amplification node 420. The amplified voltage 434 is larger in magnitude relative to the drain voltage 428 (e.g., a magnitude of the amplified voltage 434 is larger than a magnitude of the drain voltage 428 by a factor of two or more). As described above, another portion of the amplified voltage 434 may be associated with the reverse signal that propagates through the output circuit 408 to the amplification node 420.

Based on the amplified voltage 434, the output circuit 408 provides the amplified signal 206 to the output node 404. In the depicted example, the resulting amplified signal 206 is substantially opposite in phase with respect to the filtered signal 202 due to the phase rotation caused by the input transistor 410 and a configuration of the output circuit 408. The output circuit 408 also produces the feedback voltage 436 at the feedback node 422. At least a portion of the feedback voltage 436 may be associated with the filtered signal 202 or the reverse signal. The feedback voltage 436 is substantially opposite in phase with respect to the amplified voltage 434 to cause the portion of the filtered signal 202 that appears at the feedback node 422 to be substantially in phase with respect to the filtered signal 202 accepted at the input node 402. In this manner, the output circuit 408 counteracts the phase rotation caused by the input transistor 410. The feedback voltage 436 is also substantially opposite in phase with respect to the amplified voltage 434 to cause a first version of the reverse signal that appears at the feedback node 422 to be substantially opposite in phase to a second version of the reverse signal that appears at the amplification node 420.

A magnitude of the feedback voltage 436 depends on an intermediate tap position and a coupling factor (K). The intermediate tap position determines a difference between inductance amounts that respectively exist between the feedback node 422 and the supply voltage and between the amplification node 420 and the supply voltage. If the inductance amounts are equal and the coupling factor is approximately equal to one, for example, the magnitude of the feedback voltage 436 is approximately the same as the magnitude of the amplified voltage 434. This can be realized using the transformer 442, for example, if the intermediate tap is positioned in a middle of the first inductor 440-1. On the other hand, if the inductance amount between the feedback node 422 and the supply voltage is smaller than the inductance amount between the amplification node 420 and the supply voltage (e.g., the intermediate tap is positioned closer to the feedback node 422 or a smaller inductor is positioned between the supply voltage and the feedback node 422), the magnitude of the feedback voltage 436 is less than the magnitude of the amplified voltage 434.

Based on the feedback voltage 436 and a capacitance of the feedback capacitor 308, the feedback circuit 306 provides a feedback current (I_{FB}) 438 that flows between the feedback node 422 and the gate node 414 due to a voltage difference between the feedback node 422 and the gate node 414 (e.g., a magnitude difference between the feedback voltage 436 and the gate voltage 424). The feedback current 438 is represented by Equation 2 below, where Gₘ is the effective transconductance, Zₒᵤₜ is the output impedance at the amplification node 420, and A represents a voltage difference between the feedback voltage V_{FB} and the amplified voltage VA.

I_{FB}=sC_{FB}(V_{FB}−V_{G})=sC_{FB}(AGₘZₒᵤₜ−1)V_{G} Equation 2

In some implementations, a capacitance of the feedback capacitor 308 is selected to cause the feedback current 438 to be approximately equal to the gate-to-drain current 432 in magnitude, phase, and direction. In this way, the gate-to-drain current 432 is compensated for by the feedback current 438, thereby enabling the low-noise amplifier 126 to achieve a target amount of reverse isolation and gain. By causing the feedback current 438 to be approximately equal to the gate-to-drain current 432, a first version of the reverse signal that propagates through the amplifier circuit 406 and a second version of the reverse signal that propagates through the feedback circuit 306 attenuate each other at the gate node 414, which improves reverse isolation performance and a gain of the low-noise amplifier 126. As an example, the feedback current 438 may improve the reverse isolation by approximately ten decibels or more compared to another single cascode low-noise amplifier that does not include the feedback circuit 306. The reverse isolation improvement is also independent of frequency and can be realized regardless of which one of the multiple band-pass filters 122-1, 122-2 . . . 122-N (of FIG. 2) produces the filtered signal 202. In addition, a portion of the feedback current 438 can also compensate for a portion of the filtered signal 202 that propagates through the gate-to-drain capacitance 430 by amplifying the filtered signal 202 at the gate node 414, which further improves the gain of the low-noise amplifier 126. An overall gain of the low-noise amplifier 126 may increase by at least one decibel compared to the other single cascode low-noise amplifier that does not include the feedback circuit 306. Generally, a noise figure of the low-noise amplifier 126 can remain unaffected by the feedback circuit 306.

An amount of capacitance of the feedback capacitor 308 can be determined by setting Equation 1 equal to Equation 2. The resulting value of the capacitance is represented in Equation 3 below.

$${C}_{FB} = \frac{2 {C}_{GD}}{( {AG}_{m} {Z}_{out} - 1 )} \qquad Equation 3$$

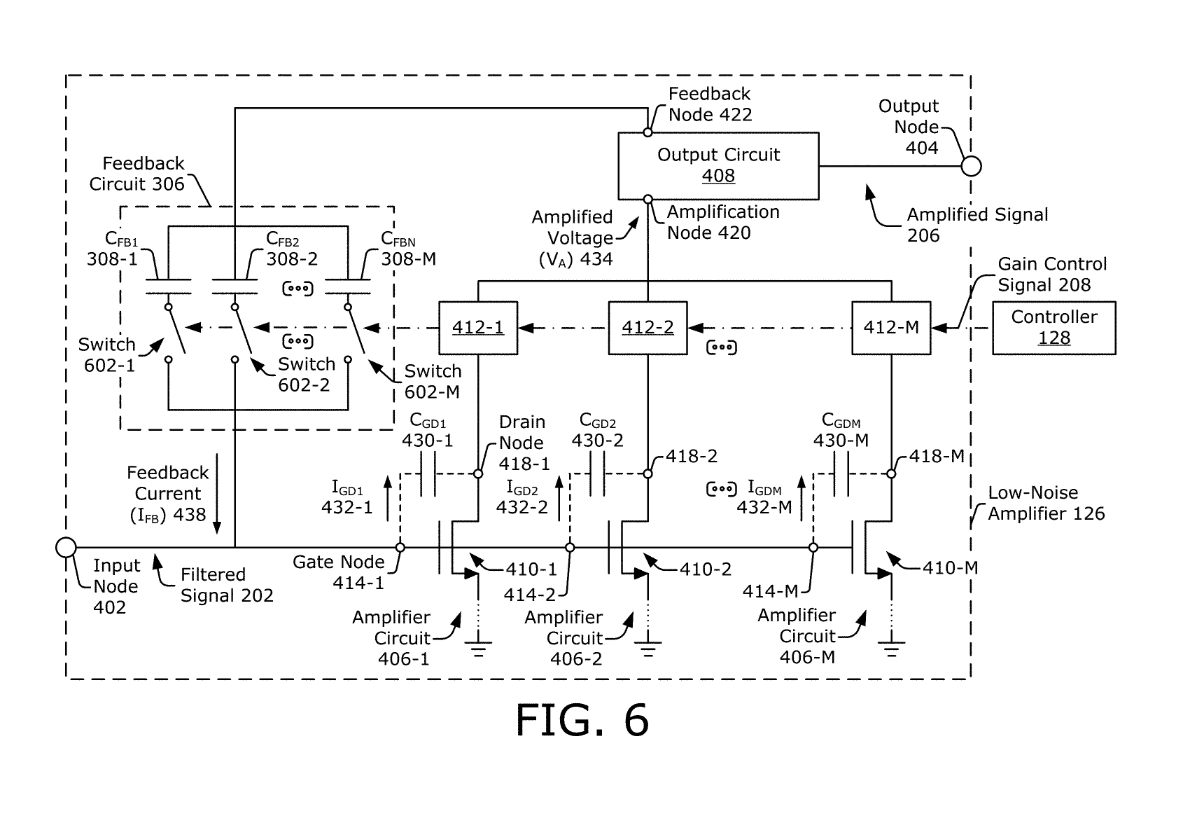

Using Equation 3, the capacitance of the feedback capacitor 308 can be set or established to cause the feedback current 438 to be approximately equal to the gate-to-drain current 432 (e.g., to cause the feedback current 438 to be less than a few milliamperes of the gate-to-drain current 432 or within hundreds of milliamperes of the gate-to-drain current 432). Example values of the feedback current 438 may range from a few microamperes to several milliamperes (e.g., the feedback current 438 may be less than approximately five milliamperes). In general, the capacitance of the feedback capacitor 308 is dependent upon the gain between the feedback node 422 and the gate node 414. As an example, a value of the denominator in Equation 3 can be approximately six, which causes the capacitance of the feedback capacitor 308 to be at least three_{—} times smaller than the gate-to-drain capacitance 430. In some implementations, the capacitance is small and minimally impacts impedance matching at the input node 402 or the output node 404. In other implementations, the capacitance may be larger to compensate for a smaller inductance between the feedback node 422 and the supply voltage. The feedback current 438 can also be adjusted to account for different gain modes of the low-noise amplifier 126, as further described with respect to FIG. 6.

FIG. 6 illustrates another example low-noise amplifier 126 for enhanced reverse isolation and gain using feedback. In the depicted configuration, the low-noise amplifier 126 includes multiple amplifier circuits 406-1, 406-2 . . . 406-M, with M representing some positive integer. Each amplifier circuit 406 includes a respective input transistor 410-1, 410-2 . . . 410-M and a respective cascode stage 412-1, 412-2 . . . 412-M. Although depicted separately, the gate nodes 414-1, 414-2 . . . 414-M are connected together to the input node 402 to jointly represent a single node. The amplifier circuits 406-1, 406-2 . . . 406-M can be individually enabled or disabled by the controller 128 via the gain control signal 208. The controller 128 can, for example, use the gain control signal 208 to set respective bias voltages that are applied to the cascode stages 412-1, 412-2 . . . 412-M to enable at least one of the amplifier circuits 406-1, 406-2 . . . 406-M. If enabled, each of the amplifier circuits 406-1, 406-2 . . . 406-M can produce at least a portion of the amplified voltage 434 at the amplification node 420. By having different quantities or combinations of the amplifier circuits 406-1, 406-2 . . . 406-M enabled, the low-noise amplifier 126 can provide different gains or amplify the filtered signal 202 by different amounts.

Although not shown in FIG. 6, the feedback circuit 306 can include a single feedback capacitor 308 (as shown in FIG. 4) whose capacitance causes the feedback current 438 to be approximately equal to a summation of the gate-to-drain currents 432-1, 432-2 . . . 432-M. The feedback capacitor 308 may also be implemented using a programmable capacitor to enable the capacitance of the feedback capacitor 308 to be adjusted by the gain control signal 208 according to which ones of the amplifier circuits 406-1, 406-2 . . . 406-M are individually enabled.

In FIG. 6, the feedback circuit 306 is shown to include multiple feedback capacitors 308-1, 308-2 . . . 308-M. Similar to the single feedback capacitor 308 implementation, a total capacitance of the multiple feedback capacitors 308-1, 308-2 . . . 308-M can be set to cause the feedback current 438 to be approximately equal to a summation of the gate-to-drain currents 432-1, 432-2 . . . 432-M. In some cases, the feedback circuit 306 may include a network of feedback capacitors 308 and switches 602 to enable the total capacitance to be adjusted based on which ones of the amplifier circuits 406-1, 406-2 . . . 406-M are enabled. For example, the multiple feedback capacitors 308-1, 308-2 . . . 308-M can be connected to respective switches 602-1, 602-2 . . . 602-M, whose states (e.g., open and closed states) are controlled via the gain control signal 208. In this way, the controller 128 can connect or disconnect the feedback capacitors 308-1, 308-2 . . . 308-M to or from the input node 402 to achieve a target total capacitance. This enables the feedback circuit 306 to adjust the feedback current 438 according to the different gain modes of the low-noise amplifier 126.

In one implementation, the feedback capacitors 308-1, 308-2 . . . 308-M are respectively connected in series with the switches 602-1, 602-2 . . . 602-M. These series-connected capacitors and switches are further connected together in parallel between the feedback node 422 and the input node 402, which is depicted in FIG. 6. Using the switches 602-1, 602-2 . . . 602-M, the total capacitance can be adjusted by connecting different combinations of the feedback capacitors 308-1, 308-2 . . . 308-M to the input node 402. The parallel branches of the feedback circuit 306 can also be associated with respective amplifier circuits 406-1, 406-2 . . . 406-M to provide respective portions of the feedback current 438 that are approximately equal to the respective gate-to-drain current 432-1, 432-2 . . . 432-M. In this instance, a quantity of the feedback capacitors 308-1, 308-2 . . . 308-M equals a quantity of the amplifier circuits 406-1, 406-2 . . . 406-M; however, different numbers may alternatively be implemented.

Although not shown, another implementation may include the multiple feedback capacitors 308-1, 308-2 . . . 308-M respectively connected in parallel with the switches 602-1, 602-2 . . . 602-M. These parallel-connected feedback capacitors and switches can be further connected together in series between the feedback node 422 and the input node 402. In this way, the switches 602-1, 602-2 . . . 602-M, which enable different combinations of the feedback capacitors 308-1, 308-2 . . . 308-M to be bypassed or not bypassed (e.g., bypassed or engaged, respectively). In general, the feedback circuit 306 can include any network of feedback capacitors 308 and switches 602 that are connected in series, in parallel, or in a combination thereof.

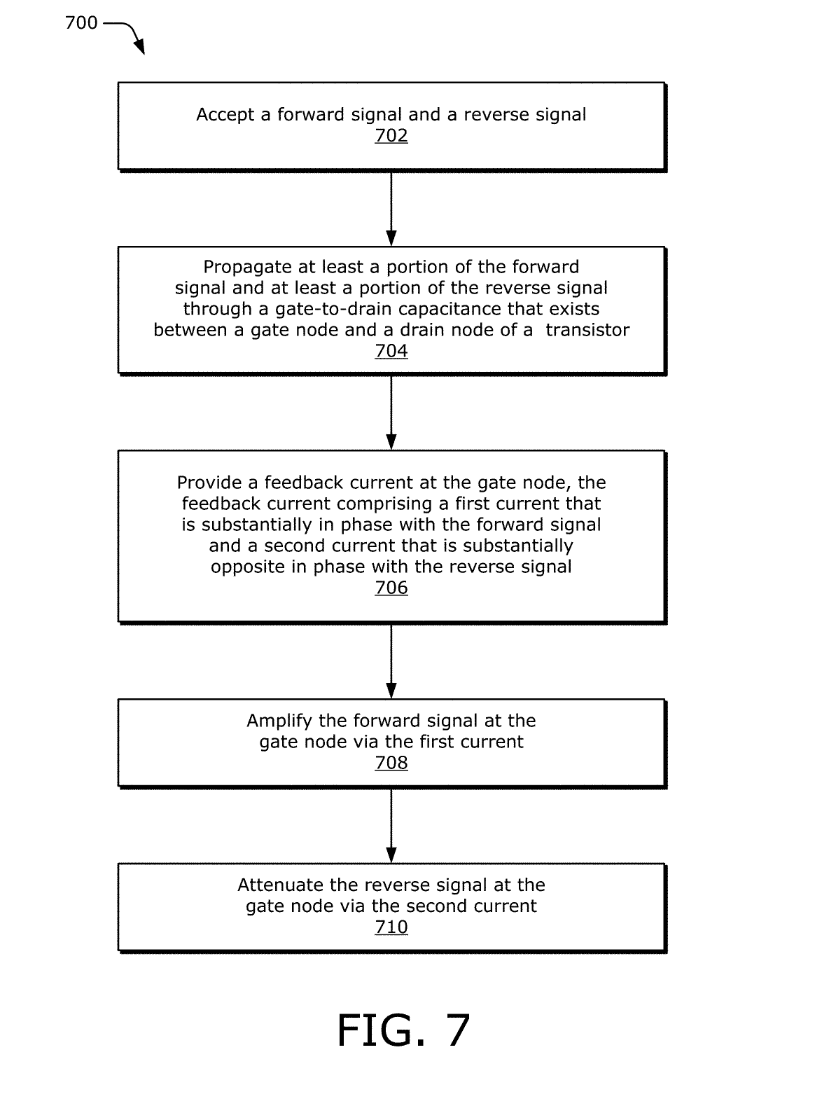

FIG. 7 is a flow diagram illustrating an example process 700 for enhanced reverse isolation and gain using feedback. The process 700 is described in the form of a set of blocks 702-710 that specify operations that can be performed. However, operations are not necessarily limited to the order shown in FIG. 7 or described herein, for the operations may be implemented in alternative orders or in fully or partially overlapping manners. Operations represented by the illustrated blocks of the process 700 may be performed by a low-noise amplifier 126 (e.g., of FIG. 1-4 or 6). More specifically, the operations of the process 700 may be performed by one or more amplifier circuits 406, an output circuit 408, or a feedback circuit 306, as shown in FIG. 4 or 6.

At 702, a forward signal and a reverse signal are accepted. The low-noise amplifier 126, for example, accepts the filtered signal 202 at the input node 402, as shown in FIG. 4, and a reverse signal at the output node 404. The reverse signal may comprise a spurious signal or a reflected portion of the amplified signal 206 shown in FIG. 4.

At 704, at least a portion of the forward signal and at least a portion of the reverse signal propagate through a gate-to-drain capacitance that exists between a gate and a drain of a transistor. For example, at least a portion of the filtered signal 202 and at least a portion of the reverse signal propagate through the gate-to-drain capacitance 430, which exists between the gate node 414 and the drain node 418 of the input transistor 410, as shown in FIG. 4. The input node 402 may provide a gate voltage 424 at the gate node 414 based on the filtered signal 202 and the output circuit 408 may produce a portion of the amplified voltage 434 at the amplification node 420 based on the reverse signal.

At 706, a feedback current is provided at the gate node. The feedback current comprises a first current that is substantially in phase with the filtered signal and a second current that is substantially opposite in phase with the reverse signal. For example, the feedback circuit 306 provides the feedback current 438 at the gate node 414 based on the feedback voltage 436 and a capacitance of the feedback capacitor 308. The capacitance of the feedback capacitor 308 is based on the gate-to-drain capacitance 430, as shown in Equation 3. The output circuit 408 produces the feedback voltage 436 based on an amplified voltage 434 at the amplification node 420 and a voltage at the output node 404. Example implementations of the output circuit 408 include the transformer 442, the chock 444, or the autotransformer 446, as shown in FIG. 4. The output circuit 408 causes the feedback voltage 436 to be substantially opposite in phase with respect to the amplified voltage 434 at the amplification node 420. In this way, a portion of the feedback current 438 is substantially in phase with the filtered signal 202 accepted at the input node 402 and another portion of the feedback current 438 is substantially opposite in phase with a version of the reverse signal that is provided at the amplification node 420.

At 708, the forward signal is amplified at the gate node via the first current. For example, the portion of the feedback current 438 that is in phase with the filtered signal 202 amplifies the filtered signal 202 at the gate node 414.

At 710, the reverse signal is attenuated at the gate node via the second current. For example, the other portion of the feedback current 438 that is opposite in phase with the version of the reverse signal that propagates through the amplifier circuit 406 causes the reverse signal to be attenuated at the gate node 414.

By providing the feedback current 438 in a manner that is approximately equal to the gate-to-drain current 432, reverse isolation and gain performance of the low-noise amplifier 126 is increased relative to other single cascode low-noise amplifier circuit designs that do not include the feedback circuit 306. With enhanced reverse isolation and gain, the low-noise amplifier 126 can comprise a single cascode stage, provide sufficient amplification using a smaller supply voltage, and mitigate the effects of impedance mismatching.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
an input node, an amplification node, and a feedback node;
an output circuit connected between the amplification node and the feedback node;
at least one amplifier circuit connected between the input node and the amplification node, the at least one amplifier circuit including:
an input transistor having a gate node and a drain node, the gate node connected to the input node; and
a cascode stage connected between the drain node and the amplification node; and
a feedback circuit including at least one feedback capacitor connected between the feedback node and the input node.

2. The apparatus of claim 1, wherein the output circuit is configured to produce, at the feedback node, a feedback voltage that is substantially opposite in phase to an amplified voltage at the amplification node.

3. The apparatus of claim 2, wherein the output circuit includes a transformer and an intermediate tap, an inductor of the transformer is connected between the amplification node and the feedback node, the intermediate tap is connected to the inductor and is configured to be connected to a power supply, the inductor and the intermediate tap are jointly configured to produce the feedback voltage at the feedback node.

4. The apparatus of claim 2, wherein the output circuit comprises a choke or an autotransformer that is connected between the amplification node and the feedback node and configured to produce the feedback voltage at the feedback node.

5. The apparatus of claim 2, wherein the at least one feedback capacitor is configured to provide a feedback current at the gate node based on the feedback voltage, the feedback current provides at least a portion of a gate-to-drain current that flows between the gate node and the drain node during operation through a gate-to-drain capacitance that exists between the gate node and the drain node.

6. The apparatus of claim 5, wherein:
the input node is configured to accept a forward signal and provide at least a portion of a gate voltage at the gate node based on the forward signal; and
the at least one feedback capacitor and the output circuit are jointly configured to cause at least a portion of the feedback current to be substantially in phase with the forward signal at the gate node.

7. The apparatus of claim 6, wherein:
the input transistor is configured to produce, based on the forward signal, at least a portion of a drain current that causes a drain voltage at the drain node to be substantially opposite in phase to the gate voltage at the gate node;
the cascode stage is configured to produce, at the amplification node, at least a portion of the amplified voltage, the amplified voltage being larger in magnitude than the drain voltage; and
the output circuit is configured to produce an amplified signal at an output node based on the amplified voltage.

8. The apparatus of claim 5, wherein:
the output circuit is configured to accept a reverse signal; and
the at least one feedback capacitor and the output circuit are jointly configured to cause the reverse signal to be attenuated at the input node.

9. The apparatus of claim 8, wherein
the output circuit is configured to:
produce, at the feedback node, at least a portion of the feedback voltage based on the reverse signal; and
produce, at the amplification node, at least a portion of the amplified voltage at the amplification node based on the reverse signal, the portion of the amplified voltage being substantially opposite in phase to the portion of the feedback voltage;
the at least one amplifier circuit is configured to propagate the reverse signal from the amplification node to the gate node through the gate-to-drain capacitance; and
the at least one feedback capacitor and the output circuit are jointly configured to cause at least a portion of the feedback current to be substantially opposite in phase to the reverse signal that propagates from the amplification node to the gate node to cause the reverse signal to be attenuated at the input node.

10. The apparatus of claim 5, wherein the at least one feedback capacitor is configured to provide the feedback current to be approximately equal to the gate-to-drain current.

11. The apparatus of claim 10, wherein the at least one feedback capacitor is configured to have a capacitance that is at least three times smaller than the gate-to-drain capacitance.

12. The apparatus of claim 1, wherein:
the input transistor comprises a common-source amplifier; and
the cascode stage comprises a common-gate amplifier.

13. The apparatus of claim 1, wherein the at least one amplifier circuit includes another amplifier circuit, the other amplifier circuit including:
another input transistor having another gate node and another drain node, the other gate node connected to the input node; and
another cascode stage connected between the other drain node of the other input transistor and the amplification node.

14. The apparatus of claim 13, wherein the at least one feedback capacitor is configured to provide, at the input node, a feedback current to be approximately equal to a summation of a gate-to-drain current that flows between the gate node and the drain node and another gate-to-drain current that flows between the other gate node and the other drain node during operation.

15. The apparatus of claim 13, wherein:
the at least one feedback capacitor includes a first feedback capacitor connected in parallel with a second feedback capacitor;
the first feedback capacitor is configured to provide a portion of a feedback current, the portion approximately equal to a gate-to-drain current that flows between the gate node and the drain node during operation; and
the second feedback capacitor is configured to provide another portion of the feedback current, the other portion approximately equal to another gate-to-drain current that flows between the other gate node and the other drain node during operation.

16. The apparatus of claim 15, wherein the feedback circuit includes:
a first switch connected in series with the first feedback capacitor between the feedback node and the input node; and
a second switch connected in series with the second feedback capacitor between the feedback node and the input node.

17. The apparatus of claim 16, wherein:
the first switch is configured to be in a closed state or an open state based on the at least one amplifier circuit being enabled or disabled, respectively; and
the second switch is configured to be in the closed state or the open state based on the other amplifier circuit being enabled or disabled, respectively.

18. The apparatus of claim 1, wherein:
the at least one feedback capacitor includes a first feedback capacitor connected in series with a second feedback capacitor; and
the feedback circuit includes:
a first switch connected in parallel with the first feedback capacitor, the first switch configured to bypass or engage the first feedback capacitor; and
a second switch connected in parallel with the second feedback capacitor, the second switch configured to bypass or engage the second feedback capacitor.

19. An apparatus comprising:
an input node, an amplification node, and a feedback node;
at least one amplifier circuit connected between the input node and the amplification node, the at least one amplifier circuit including:
an input transistor having a gate node, a drain node, and a gate-to-drain capacitance, the gate node connected to the input node; and
a cascode stage connected between the drain node of the input transistor and the amplification node;
mutual coupling means for producing, at the feedback node, a feedback voltage that is substantially opposite in phase to an amplified voltage at the amplification node, the mutual coupling means connected between the amplification node and the feedback node; and
feedback means for providing, based on the feedback voltage, a feedback current at the input node, the feedback current providing at least a portion of a gate-to-drain current that flows between the gate node and the drain node through the gate-to-drain capacitance during operation.

20. The apparatus of claim 19, wherein:
the mutual coupling means is configured to produce, at the feedback node, the feedback voltage substantially in phase to a gate voltage at the gate node; and
the feedback means is configured to provide, at the input node, the feedback current in a manner that is approximately equal in magnitude, phase, and direction to the gate-to-drain current.

21. The apparatus of claim 20, wherein:
the input node is configured to accept a forward signal; and
the mutual coupling means and the feedback means are jointly configured to cause at least a portion of the feedback current to be substantially in phase with the forward signal at the gate node.

22. The apparatus of claim 21, further comprising an output node connected to the mutual coupling means, the output node configured to accept a reverse signal,
wherein the mutual coupling means and the feedback means are jointly configured to cause the reverse signal to be attenuated at the input node.

23. The apparatus of claim 22, wherein:
the mutual coupling means if configured to:
produce, at the feedback node, at least a portion of the feedback voltage based on the reverse signal; and
produce, at the amplification node, at least a portion of the amplified voltage based on the reverse signal, the portion of the amplified voltage being substantially opposite in phase to the portion of the feedback voltage;
the at least one amplifier circuit is configured to propagate, based on the portion of the amplified voltage, a first version of the reverse signal from the amplification node to the gate node through the gate-to-drain capacitance; and
the feedback means is configured to propagate, based on the portion of the feedback voltage, a second version of the reverse signal from the feedback node to the gate node to cause the reverse signal to be attenuated at the input node.

24. The apparatus of claim 19, wherein:
the at least one amplifier circuit includes another amplifier circuit connected between the input node and the amplification node, the other amplifier circuit including:
another input transistor having another gate node and another drain node, the other gate node connected to the input node; and
another cascode stage connected between the other drain node of the other input transistor and the amplification node; and
the feedback means is configured to provide, at the input node, the feedback current in a manner that is substantially equal to a summation of the gate-to-drain current that flows between the gate node and the drain node and another gate-to-drain current that flows between the other gate node and the other drain node during operation.

25. The apparatus of claim 24, wherein:
the at least one amplifier circuit is configured to be enabled or disabled via a bias voltage that is applied to the cascode stage;
the other amplifier circuit is configured to be enabled or disabled via another bias voltage that is applied to the other cascode stage; and
the feedback means is configured to adjust a magnitude of the feedback current based on whether the at least one amplifier circuit and the other amplifier circuit are respectively enabled or disabled.

26. A method for enhanced reverse isolation and gain using feedback, the method comprising:
accepting a forward signal and a reverse signal;
propagating at least a portion of the forward signal and at least a portion of the reverse signal through a gate-to-drain capacitance that exists between a gate node and a drain node of a transistor;
providing a feedback current at the gate node, the feedback current comprising a first current that is substantially in phase with the forward signal and a second current that is substantially opposite in phase with the reverse signal;
amplifying the forward signal at the gate node via the first current; and
attenuating the reverse signal at the gate node via the second current.

27. An apparatus comprising:
multiple band-pass filters having different frequency bands;
a switch module connected to the multiple band-pass filters; and
a low-noise amplifier connected to the switch module, the low-noise amplifier including:
at least one amplifier circuit connected to the switch module and including an input transistor;
an output circuit connected to the at least one amplifier circuit at an amplification node, the output circuit configured to produce, at a feedback node, a feedback voltage that is substantially opposite in phase to an amplified voltage at the amplification node; and
a feedback circuit connected between the feedback node and the at least one amplifier circuit, the feedback circuit configured to provide a feedback current to the at least one amplifier circuit based on the feedback voltage.

28. The apparatus of claim 27, wherein:
a selected band-pass filter of the multiple band-pass filters is configured to produce a filtered signal;
the switch module is configured to connect the selected band-pass filter to the low-noise amplifier;
the at least one amplifier circuit is configured to amplify the filtered signal using the input transistor to produce at least a portion of the amplified voltage at the amplification node;
the output circuit configured to:
provide, based on the portion of the amplified voltage, an amplified signal to an output node of the low-noise amplifier; and
produce the feedback voltage based on the amplified signal; and
the feedback circuit is coupled to the at least one amplifier circuit at a gate node and is configured to provide the feedback current based on the feedback voltage, at least a portion of the feedback current being substantially in phase with the filtered signal at the gate node.

29. The apparatus of claim 28, wherein:
the output circuit is configured to:
accept a reverse signal from the output node of the low-noise amplifier;
produce the feedback voltage based on both the amplified signal and the reverse signal; and
produce another portion of the amplified voltage based on the reverse signal;
the at least one amplifier circuit is configured to propagate, based on the other portion of the amplified voltage, the reverse signal from the amplification node to the gate node; and
the feedback circuit is configured to provide the feedback current to the at least one amplifier circuit, another portion of the feedback current being substantially opposite in phase with the reverse signal that propagates to the gate node via the at least one amplifier circuit.

30. The apparatus of claim 29, wherein the feedback circuit and the output circuit are jointly configured to:
cause the filtered signal to be amplified at the gate node based on the portion of the feedback current; and
cause the reverse signal to be attenuated at the input node based on the other portion of the feedback current.
